(19) United States
(12) Patent Application Publication
(10) Pub. No.: US 2025/0151340 A1
(43) Pub. Date: May 8, 2025

(54) POWER DEVICE PROGNOSTICS WITH QUANTUM SENSING THROUGH 2-D MATERIALS

(71) Applicant: Toyota Motor Engineering & Manufacturing North America, Inc., Plano, TX (US)

(72) Inventors: Ercan Mehmet DEDE, Ann Arbor, MI (US); Yohei IWAHASHI, Plano, TX (US); Alejandro RUIZ, Ann Arbor, MI (US); Debasish BANERJEE, Ann Arbor, MI (US); Shailesh N. JOSHI, Ann Arbor, MI (US); Paul Donald SCHMALENBERG, Ann Arbor, MI (US)

(73) Assignees: Toyota Motor Engineering & Manufacturing North America, Inc., Plano, TX (US); Toyota Jidosha Kabushiki Kaisha, Aichi-ken (JP)

(21) Appl. No.: 18/502,649

(22) Filed: Nov. 6, 2023

(51) Int. Cl. H01L 29/66; G01R 31/26; G01R 31/265; H01L 23/00; H01L 23/14; H01L 23/66; H01L 25/16

(52) U.S. Cl. CPC H10D 48/383; G01R 31/2642; G01R 31/265; H01L 23/147; H01L 23/66; H01L 24/08; H01L 25/167; H01L 2224/08225

(57) ABSTRACT

Systems, apparatuses, and methods provide for predicting a remaining useful life of semiconductors utilizing quantum sensors. A layer of 2-D material of the quantum sensor is excited via a microwave field source and a light source of a quantum sensor while also subject to a magnetic field, where the quantum sensor is located adjacent a semiconductor device. The excitation of the layer of 2-D material is sensed, via a photodetector of the quantum sensor. A magnetic field, a temperature, and/or a strain field effect of the semiconductor device are measured based on the sensed excitation of the layer of 2-D material. A remaining useful life of the semiconductor device is predicted based on one or more of the measured magnetic field, the measured temperature, or the measured strain field effect.

### TECHNICAL FIELD

Embodiments generally relate to quantum sensing. More particularly, embodiments relate to predicting a remaining useful life of a semiconductor device utilizing quantum sensing.

### BACKGROUND

The process of creating the mechanical die attachment between a power semiconductor device and substrate often causes thermally induced mechanical stress in the bond layer of the package. Such thermally induced mechanical stress is often worsened by the thermal cycling of the resultant package during normal operation.

Thermal cycling of the power electronics package further causes plastic work and strain to accumulate in a bond layer (e.g., solder, silver sinter, transient liquid-phase) material. Such operations impact the remaining useful life (RUL) or eventual failure of the power semiconductor device.

### BRIEF DESCRIPTION OF THE DRAWINGS

Various examples will be described below by referencing the following drawings, in which:

FIG. 1 is a diagram illustrating a thermally induced mechanical stress;

FIG. 2 is a cross sectional side view diagram illustrating a quantum sensor system according to an example;

FIG. 3 is a top view with corresponding cross sectional side view diagrams illustrating a quantum sensor system according to an example;

FIG. 4 is a top view and corresponding cross sectional side view diagram illustrating a quantum sensor system according to an example;

FIG. 5 is a side view diagram illustrating a quantum sensor system according to an example;

FIG. 6 is a top view diagram illustrating various designs for a 2-D material layer according to an example;

FIG. 7 is a side view diagram illustrating a quantum sensor system according to an example;

FIG. 8 is a side view diagram illustrating a quantum sensor system according to an example;

FIG. 9 is an illustration of a graph of the measured effect of a magnetic field according to an example;

FIG. 10 is an illustration of a graph of the measured effect of temperature according to an example;

FIG. 11 is another illustration of a graph of the measured effect of strain according to an example;

FIG. 12 is another illustration of a graph of the measured effect of strain according to an example;

FIG. 13 is an illustration of a flowchart of an example method for quantum sensor operation according to an example;

FIG. 14 is a block diagram illustrating a computer program product according to an example;

FIG. 15 is a block diagram illustrating an example computing apparatus according to an example;

FIG. 16 is a block diagram illustrating a hardware apparatus including a semiconductor package according to an example; and

FIG. 17 is a diagram illustrating a vehicle according to an example.

### DETAILED DESCRIPTION

As described above, thermally induced mechanical stress impacts the remaining useful life (RUL) or eventual failure of the power semiconductor device. Often temperature sensors may be utilized to monitor temperature to approximate thermally induced mechanical stress.

As will be discussed in greater detail below, improved sensing can be achieved through the use of 2-D materials. Such 2-D materials may be utilized to sense more aspects than only temperature. For example, such 2-D materials can be utilized to sense magnetic, temperature, and strain fields. As an example, quantum sensing and imaging with spin defects in hexagonal boron nitride (hBN) can be utilized to sense magnetic, temperature, and strain fields.

Different from research describing the basic functionality of 2-D materials for strain sensing, the techniques described herein describe the application of a functionalized 2-D material such as hBN to a power semiconductor device in a power module package for the detection of plastic work and accumulated strain in the die attach bond line of the electronics package. Typically, such strain signals might be measured using a strain gauge or derived from a change in the temperature of the device over time. However, strain gauges in particular tend to be impractical for such microelectronics applications, and device temperature serves only as a proxy for the actual state field of interest (e.g., the strain). Thus, with the techniques described herein, the time variation of the measured signal as it directly relates to strain can be precisely measured in a highly sensitive fashion. This strain signal may then be used for prognostics in the prediction of the remaining useful life (RUL) of the power semiconductor device/electronics package.

As will be discussed in greater detail below, some systems, apparatuses, and methods described herein address predicting a remaining useful life of semiconductors utilizing quantum sensors. A 2-D material of the quantum sensor is excited via a microwave field source and a light source of a quantum sensor, where the quantum sensor is located adjacent a semiconductor device. The excitation of the 2-D material is sensed, via a photodetector of the quantum sensor. A magnetic field, a temperature, and/or a strain field effect of the semiconductor device are measured based on the sensed excitation of the layer of 2-D material. A remaining useful life of the semiconductor device is predicted based on one or more of the measured magnetic field, the measured temperature, or the measured strain field effect.

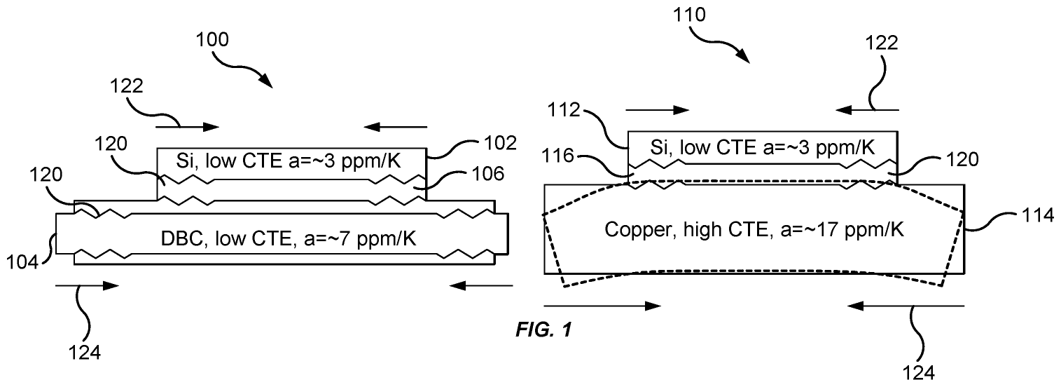

FIG. 1 is a diagram illustrating a thermally induced mechanical stress. As illustrated, a power module 100 includes a semiconductor device (e.g., Si IGBT, SIC MOSFET, GaN device, diamond device, Ga2O3 device, etc.) or chip 102 affixed to a direct bond copper (DBC) substrate 104 via a bond layer 106. Similarly, power module 110 includes a semiconductor device or a chip 112 affixed to a copper substrate 114 via a bond layer 116.

Thermal cycling of the power module 100 and power module 110 both result in thermal stress 120, chip shrinkage 122, and substrate shrinkage 124. In some instances, and depending on the package fabrication process, the built-in thermal stress 120 may be more significant in the power module 100 (e.g., having the direct bond copper (DBC) substrate 104) while the substrate shrinkage 124 may be more significant in the power module 110 (e.g., having the copper substrate 114).

As shown, the process of creating the mechanical die attachment between a power semiconductor device and substrate, and/or the thermal cycling of the resultant package during normal operation, causes built-in thermally induced mechanical stress in the bond layer of the package.

Thermal cycling of the power electronics package further causes plastic work and strain to accumulate in the bond layer (e.g., solder, silver sinter, transient liquid-phase) material over time.

The nonlinear deformation of the material in the bond line over time and the evolution of the bond line strain eventually leads to the initiation of cracks in the bond line typically at the corners or edges of the device. This crack initiation process can be further numerically predicted, and established or developed lifetime models may then be used to estimate the number of cycles to failure for the corner or edge regions of the device.

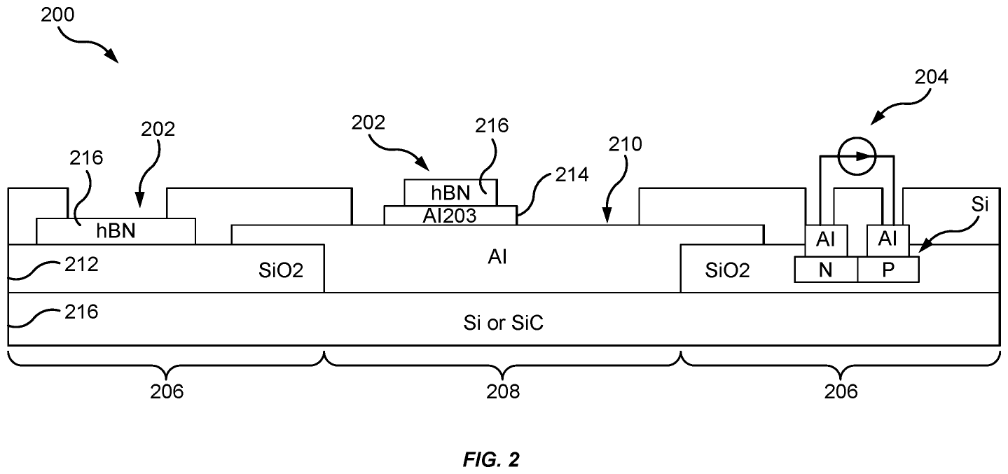

FIG. 2 is a cross sectional side view diagram illustrating a quantum sensor system 200 according to an example. In the illustrated example, quantum sensor system 200 includes a quantum sensor 202 in addition to one or more temperature sensors 204 (e.g., a temperature sensing diode or the like). In some implementations, temperature sensors 204 may be excluded from the quantum sensor system 200.

In some implementations, quantum sensors 202 comprising 2-D material layers are located in non-active areas 206 and/or active areas 208 of the semiconductor device 210. In some examples, semiconductor substrate 212 is composed of silicon, silicon carbide, the like, and/or combinations thereof.

In some implementations, a dielectric layer 214 is located between the semiconductor device 210 and a 2-D material 216 of the quantum sensors 202. As used herein the term “2-D material” refers to materials of crystalline solids (e.g., hexagonal boron nitride (hBN)) having a thickness of one to a few hundred atomic layers.

For example, the 2-D material 216 may be composed of hexagonal boron nitride functionalized with spin defects for strain sensing. In other implementations the 2-D material 216 may be composed of a nano-diamond material layer (e.g., for magnetic field detection). Such a hexagonal boron nitride 2-D material layer is deposited via tape transfer or chemical vapor deposition prior to passivation when the dielectric layer is silicon dioxide, for example. Similarly, such a hexagonal boron nitride 2-D material layer (hBN) is deposited via tape transfer or chemical vapor deposition as a final assembly step when the dielectric layer is aluminum oxide, for example.

Here, the integration of a 2-D material such as hBN may be positioned at select locations on a silicon or wide band-gap (WBG) power semiconductor device for the direct measurement of accumulated strain in the package. As shown below, relative to a power semiconductor device, the 2-D hBN material may be incorporated on to the power device in locations prone to failure (e.g., corners, edges, or hot spot regions of the chip). Here, the 2-D material may be placed on an electrically insulating landing pad (e.g., SiO2 or Al2O3) using either a tape transfer method or using a chemical vapor deposition (CVD) process.

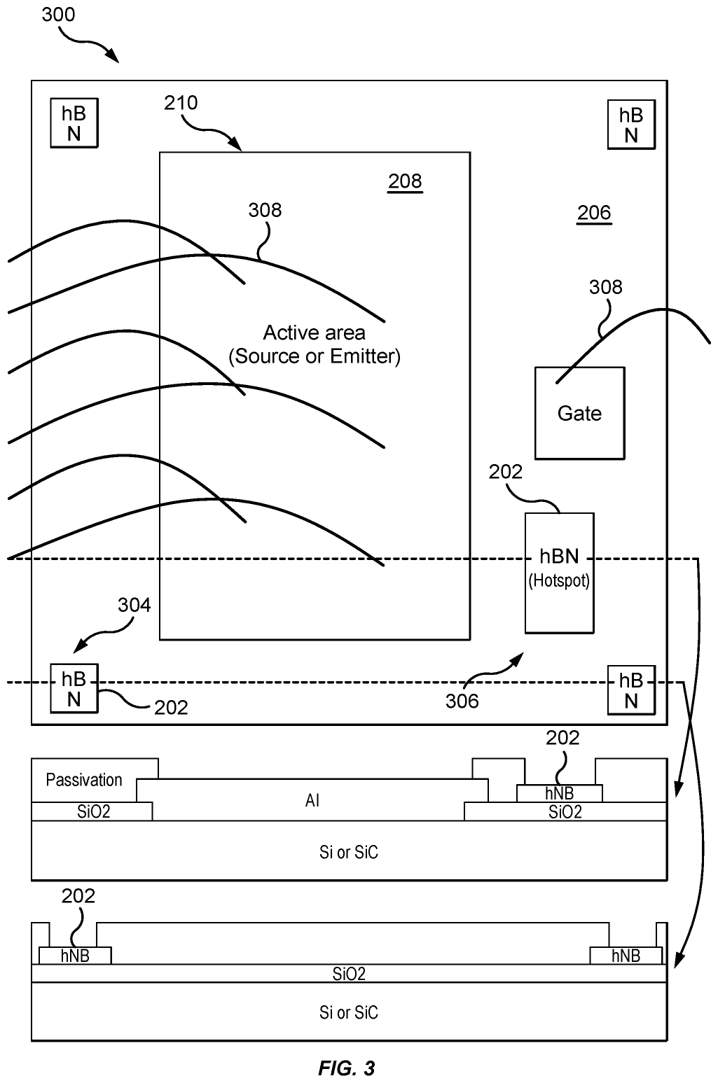

FIG. 3 is a top view with corresponding cross sectional side view diagrams illustrating a quantum sensor system 300 according to an example. In the illustrated example, semiconductor device 210 has an active area 208 and a non-active area 206. As illustrated there may be a plurality of quantum sensors 202 spaced around the semiconductor device 210.

For example, the plurality of quantum sensors 202 may be located at one or more corner regions 304 of the non-active area 206. Similarly, the plurality of quantum sensors 202 may be located at one or more wire bond free regions 306 (e.g., free of wire bonds 308) of the non-active area 206. Such wire bond free regions 306 may be selected based on hotspots of the semiconductor device 210.

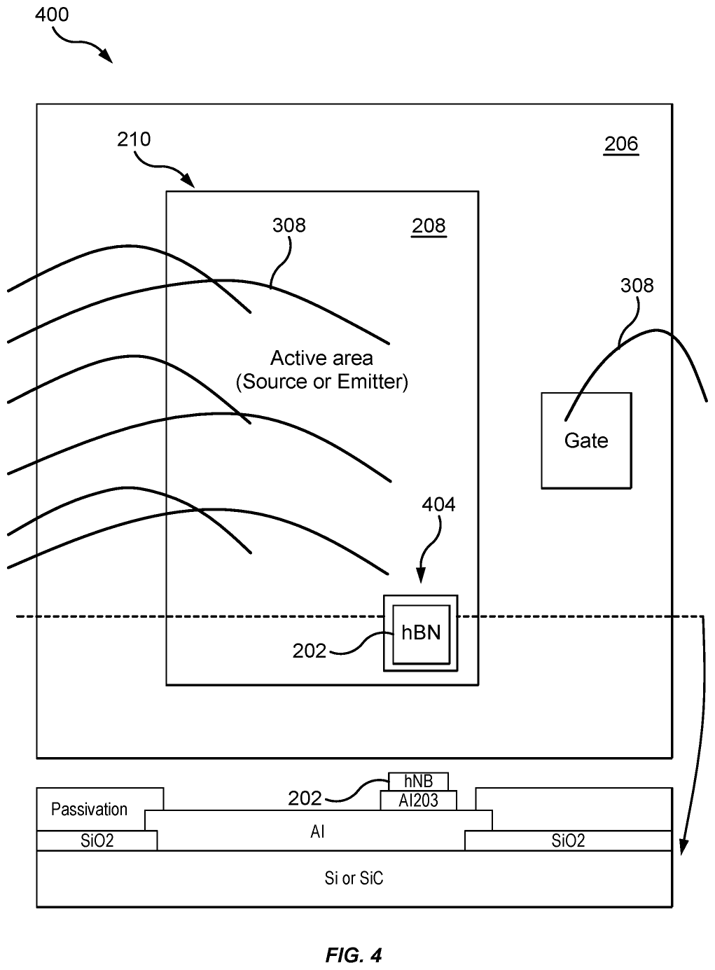

FIG. 4 is a top view and corresponding cross sectional side view diagram illustrating a quantum sensor system 400 according to an example. In the illustrated example, the plurality of quantum sensors 202 may be located at one or more wire bond adjacent regions 404 of the active area 208 of semiconductor device 210.

Referring to FIGS. 3 and 4, as mentioned above, the hBN material may be strategically integrated into the device at the non-active corners of the chip where strain is known to accumulate. Furthermore, the hBN material may be placed in non-active areas without wire bonds, which tend to be hotter due to the heat sinking effect of the wire bond itself. Additionally, or alternatively, the hBN material might be placed in the active area of the chip close to the wire bond, which also experiences strain due to the wire bond heel attachment. Accordingly, the hBN material is configured/positioned to detect the accumulation of plastic work or strain in strategic areas of the bond line including corners, hotspots, and/or wire bond regions of the device.

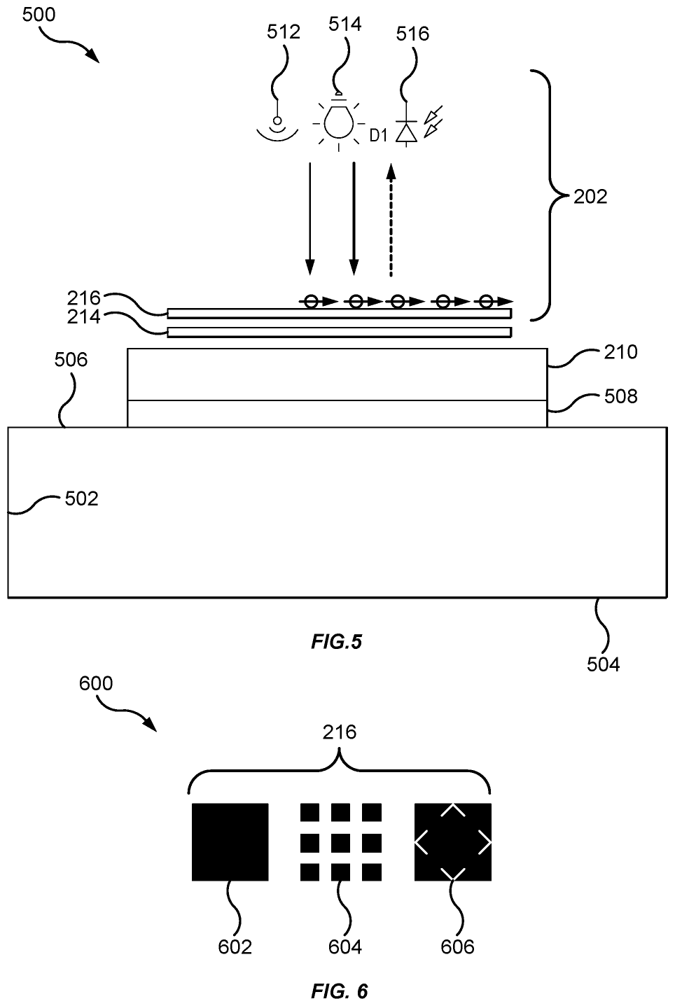

FIG. 5 is a side view diagram illustrating a quantum sensor system 500 according to an example. In the illustrated example, a substrate 502 has a first side 504 and a second side 506 positioned opposite the first side 504. A semiconductor device 210 is located on the second side 506 of the substrate 502. For example, the semiconductor device 210 is coupled to the second side 506 of the substrate 502 via a bond layer 508.

In the illustrated example, substrate 502 is a direct bond copper substrate, a copper substrate, a composite substrate (e.g., a metal matrix composite such as aluminum silicon carbide (AlSiC)), the like, and/or combinations thereof.

In some implementations, the quantum sensor 202 is located on the second side 506 of the substrate 502. For example, the quantum sensor 202 is located on the second side 506 of the substrate 502 with a dielectric layer positioned between the quantum sensor 202 and the semiconductor device 210.

In some examples, the quantum sensor 202 includes the layer of 2-D material 216. In the illustrated example, the quantum sensor further includes a microwave field source 512, a light source 514, and a photodetector 516. For example, the full quantum sensor 202 includes light source 514 for the 2-D material excitation, microwave field source 512 (e.g., an antenna) for 2-D material excitation, and photodetector 516 for collection of light from the 2-D material sample. As will be discussed in further detail below, the quantum sensor 202 is configured to measure a magnetic field, a temperature, and/or a strain field effect.

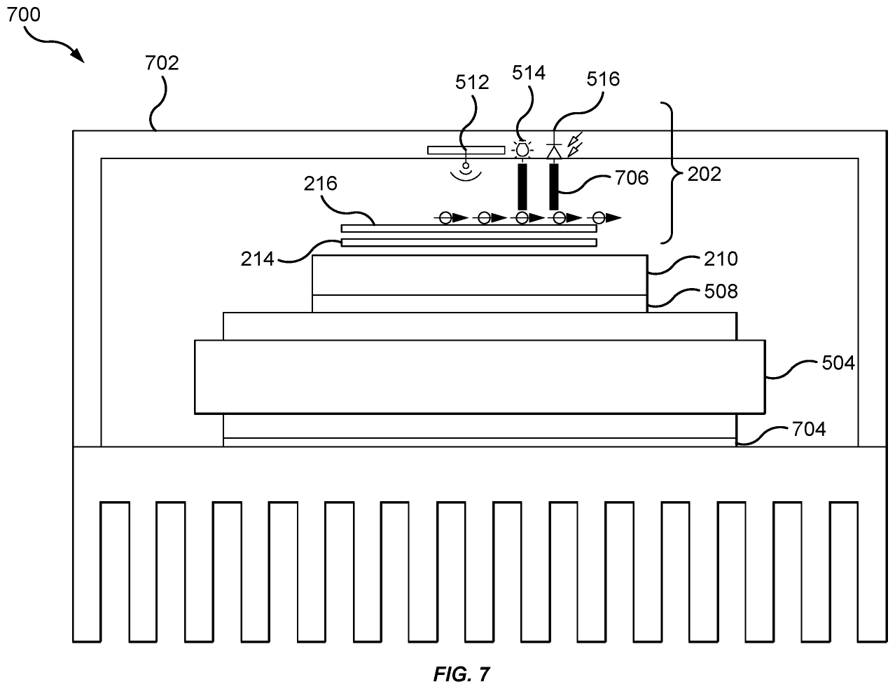

As will be described in greater detail below, a magnetic field source is also applied to the quantum sensor system 700. For example, the magnetic field source (e.g., magnetic B-field) may be applied using the inherent semiconductor device alternating current (AC) magnetic B-field. Additionally, or alternatively, a separate external AC magnetic field source may be applied. Additionally, or alternatively, a separate magnetic field source (not illustrated) may be incorporated into the quantum sensor system 700 (FIG. 7), and/or the quantum sensor system 800 (FIG. 8), discussed in greater detail below.

It will be appreciated that in implementations including a temperature sensor, the temperature sensor would likewise be located on the second side 506 of the substrate 502.

FIG. 6 is a top view diagram illustrating various designs 600 for a nano-layer of 2-D material 216 according to an example. In the illustrated example, the 2-D material 216 may be oriented and arranged to have a particular design to improve or modify performance and/or preserve material.

In some implementations, the 2-D material 216 design is a single unitary patch 602. In some examples, wherein the design is an array of a plurality of patches 604. Alternatively, or additionally, wherein the design is a discontinuous patch 606 having a geometric pattern.

FIG. 7 is a side view diagram illustrating a quantum sensor system according to an example. In the illustrated example, the semiconductor device 210 is contained within an electronics package 702. As illustrated, a thermal interface material (TIM) grease layer 704 may be located between the substrate 504 and the electronics package 702.

In some implementations, the microwave field source 512, the light source 514, and/or the photodetector 516 are incorporated into the electronics package 702 itself to be positioned above the 2-D material 216.

In some examples, the quantum sensor 202 further includes a plurality of light pipes 706 located between the light source 514 and the nano-layer of 2-D material 216 and/or located between the photodetector 516 and the 2-D material 216. The light pipes 706 are configured to channel light to/from the light source 514 and/or the photodetector 516.

As illustrated, the microwave field source 512, the light source 514, and/or the photodetector 516 may be integrated into the case of the power module package 702 with light pipe(s) 706 coupling the light source 514 and photodetector 516 to the nano-layer of 2-D material 216 regions of interest.

FIG. 8 is a side view diagram illustrating a quantum sensor system according to an example. In the illustrated example, the microwave field source 512, the light source 514, and/or the photodetector 516 are incorporated into an electronics device 806 positioned adjacent to the nano-layer of 2-D material 216.

As illustrated, the microwave field source 512, the light source 514, and/or the photodetector 516 may be integrated into the electronics device 806 as a separate semiconductor device (e.g., a printed circuit board (PCB) or chip) that is positioned on top of the power device in the package 702.

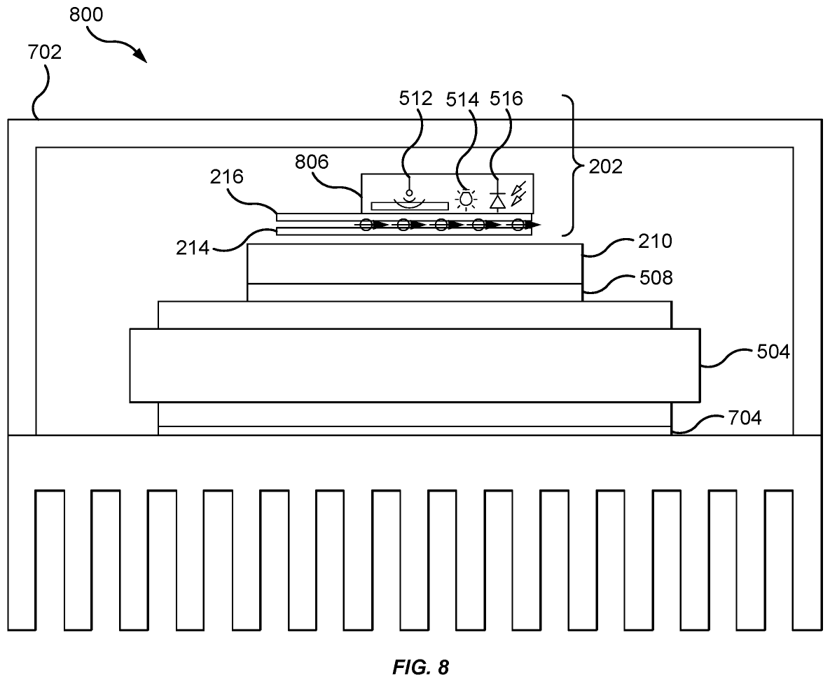

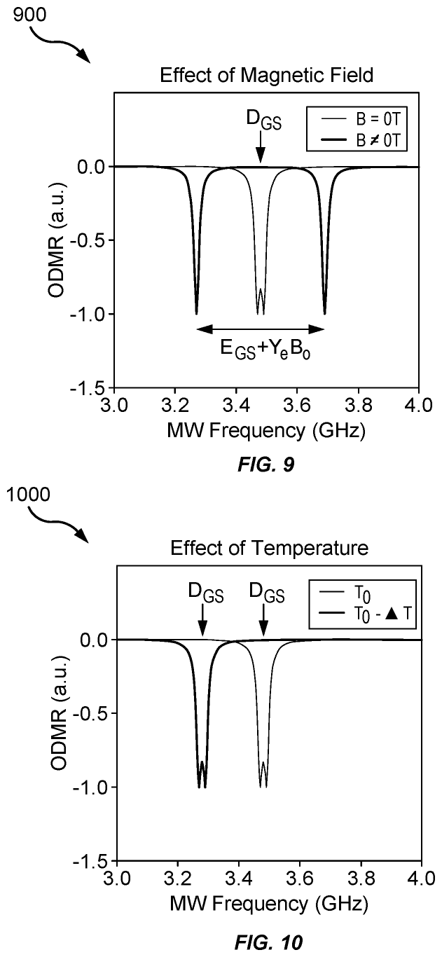

FIG. 9 is an illustration of a graph 900 of the measured effect of a magnetic field according to an example. As Illustrated, a measured magnetic field is compared to an applied magnetic field when monitoring an optically detected magnetic resonance (ODMR) response. In this example, a splitting of frequencies is observed. As will be discussed in greater detail below, FIGS. 9-12 illustrate that measurements may illustrate a shift in frequency, a splitting in frequency, and/or both a shift and splitting in frequency response based on power module package strain.

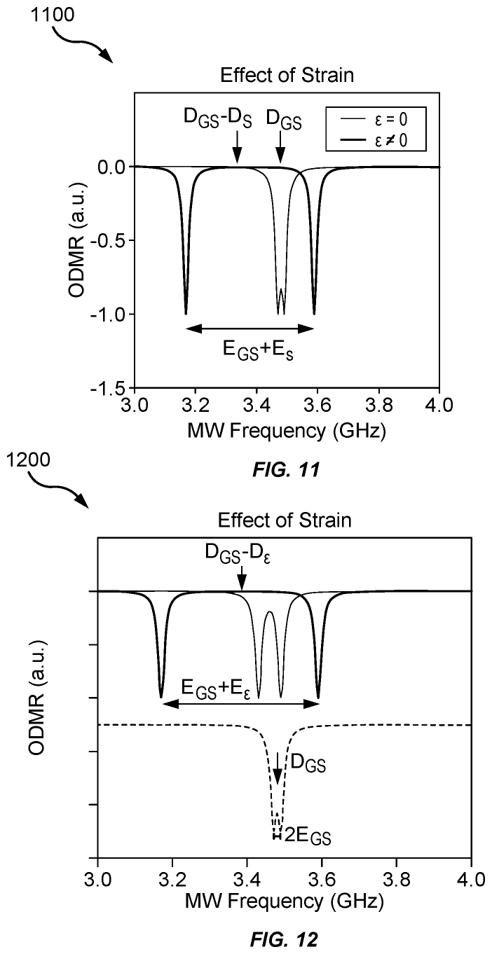

In operation, the full quantum sensor system operates based on optically detected magnetic resonance (ODMR) principles. ODMR is a double resonance technique which combines optical measurements (e.g., fluorescence, phosphorescence, absorption) with electron spin resonance spectroscopy. Here, pure magnetic field (FIG. 9), temperature (FIG. 10), and strain field (FIGS. 11 and 12) effects on the response of the 2-D hBN material are, respectively, shown. It is observed that in the strain field (FIGS. 11 and 12) effects that the application of total strain (a combination of in-plane shear and normal peel) produces both a frequency splitting and shift effect in the measured response of the material.

FIG. 10 is an illustration of a graph 1000 of the measured effect of temperature according to an example. As Illustrated, effects of temperature are measured when monitoring an optically detected magnetic resonance (ODMR) response. In this example, a shift of frequencies is observed.

FIG. 11 is another illustration of a graph 1100 of the measured effect of strain according to an example. As Illustrated, effects of strain are measured when monitoring an optically detected magnetic resonance (ODMR) response. In this example, both a splitting and shifting of frequencies is observed.

FIG. 12 is another illustration of a graph 1200 of the measured effect of strain according to an example. As Illustrated, effects of strain are measured when monitoring an optically detected magnetic resonance (ODMR) response. In this example, both a splitting and shifting of frequencies is observed. Also illustrated is a zero strain reading for comparison.

Based on the above understanding illustrated in FIGS. 9-12, the evolution of the strain response may then be measured at different points of interest over time. The accumulated plastic work effect previously described is then directly tied to the measured ODMR response, as shown in FIG. 12. In addition to the ODMR measurement, changes in the fluorescence magnitude of the 2-D material may also be tracked as a substitute for the full ODMR response. Moreover, since multiple 2-D material measurement sites may be employed on a power device, the displacement of photoluminescent measurement points may be further tracked to provide information similar to that obtained from digital image correlation (DIC) techniques. For example, fluorescence magnitude and photoluminescence site displacement are measured based on package strain to, respectively, provide ODMR and DIC-related information.

Some further elements to consider include a characterization of the bond layer, which may be done post fabrication as a baseline with subsequent interrogation to then show the change (e.g., degradation) from baseline. In some examples, interrogation may occur at regular module maintenance cycles during module off condition (e.g., at vehicle check-ups at the dealer) to avoid in-use thermal/magnetic field effects. In such a case, a separate and controlled magnetic field (e.g., AC magnetic B-field) may be manually applied for ODMR sensing purposes. This magnetic B-field field source may be applied using an external source such as an electromagnet (e.g., Helmholtz coil), or this separately excitable magnetic field source may be further integrated into the quantum sensing system. Alternatively, interrogation of the package could be performed when the module is powered on during a specified power cycle condition using the inherent semiconductor device magnetic B-field. The ODMR data may be combined with machine learning techniques for predicting an eventual remaining useful life (RUL) or predicting failure of the chip. In some implementations, time series images from the photodetector (e.g., intensity/response shift images) can be processed remotely to detect fault and identify failure modes or distinct changes in response.

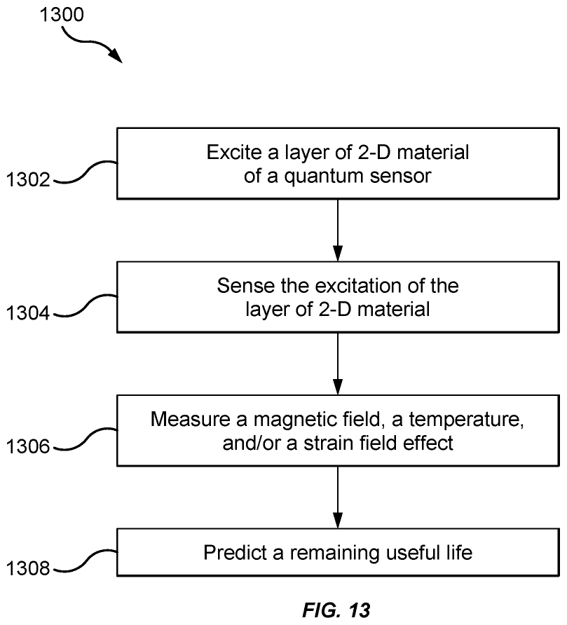

FIG. 13 shows an example method 1300 for quantum sensor operation according to an example. The method 1300 may generally be implemented in an apparatus, such as, for example, the quantum sensor system 300 (FIG. 3), the quantum sensor system 400 (FIG. 4), the quantum sensor system 500 (FIG. 5), the quantum sensor system 700 (FIG. 7), and/or the quantum sensor system 800 (FIG. 8), already discussed.

Illustrated processing block 1302 provides for exciting a layer of 2-D material of the quantum sensor. For example, a layer of 2-D material of the quantum sensor is excited, via a microwave field source, a magnetic field source and a light source of a quantum sensor. In some examples, the quantum sensor is located adjacent a semiconductor device.

As described above, the magnetic field source (e.g., magnetic B-field) may be applied using the inherent semiconductor device AC magnetic B-field. Additionally, or alternatively, a separate external AC magnetic field source may be applied. Additionally, or alternatively, a separate magnetic field source (not illustrated) may be incorporated into the quantum sensor system 700 (FIG. 7), and/or the quantum sensor system 800 (FIG. 8), already discussed.

Illustrated processing block 1304 provides for sensing the excitation of the layer of 2-D material. For example, the excitation of the layer of 2-D material is sensed, via a photodetector of the quantum sensor.

Illustrated processing block 1306 provides for measuring a magnetic field, a temperature, and/or a strain field effect. For example, one or more of a magnetic field, a temperature, or a strain field effect of the semiconductor device are measured based on the sensed excitation of the layer of 2-D material.

Illustrated processing block 1308 provides for predicting a remaining useful life. For example, a remaining useful life of the semiconductor device is predicted based on the measured magnetic field, the measured temperature, and/or the measured strain field effect and a subsequent processing of the data.

In some implementations, the method 1300 further includes channeling light from the light source and light to the photodetector. For example, light from the light source and light to the photodetector is channeled via a plurality of light pipes. The light pipes are located between the light source and the nano-layer of 2-D material and located between the photodetector and the nano-layer of 2-D material.

In some examples, the measuring is conducted using of an optically detected magnetic resonance measurement, a digital image correlation measurement, and/or a fluorescence magnitude measurement.

In some implementations, the measuring is conducted using a baseline measurement and a plurality of subsequent measurements.

In an example, the method 1300 may be implemented in computer readable instructions (e.g., software), configurable computer readable instructions (e.g., firmware), fixed-functionality computer readable instructions (e.g., hardware), etc., or any combination thereof.

In some examples, it will be appreciated that some or all of the operations in method 1300 may be performed at least in part by cloud processing.

It will be appreciated that some or all of the operations in method 1300 are described using a “pull” architecture (e.g., polling for new information followed by a corresponding response) may instead be implemented using a “push” architecture (e.g., sending such information when there is new information to report), and vice versa.

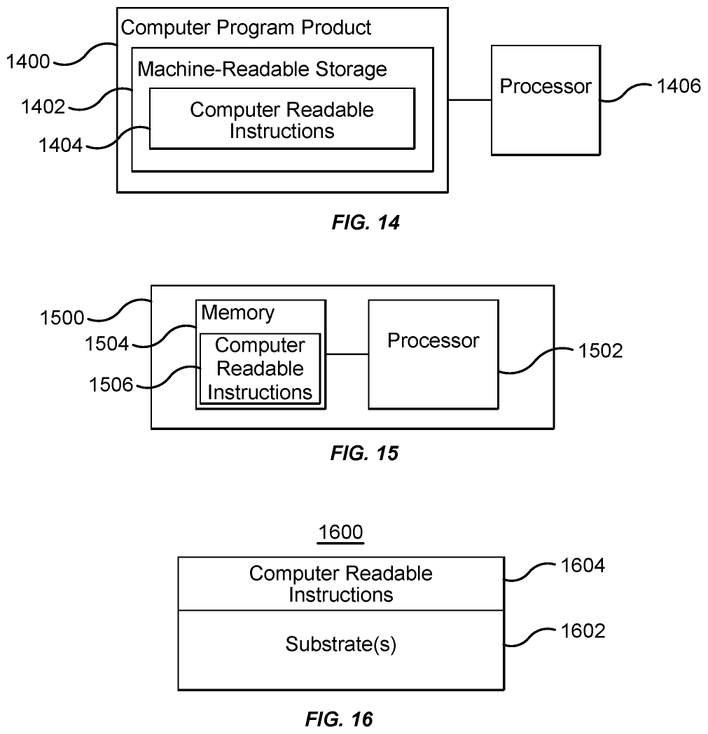

FIG. 14 illustrates a block diagram of an example computer program product 1400. In some examples, as shown in FIG. 14, computer program product 1400 includes a machine-readable storage 1402 that may also include computer readable instructions 1404. In some implementations, the machine-readable storage 1402 may be implemented as a non-transitory machine-readable storage. In some implementations the computer readable instructions 1404, which may be implemented as software, for example. In an example, the computer readable instructions 1404, when executed by a processor 1406, implement one or more aspects of the method 1300 (FIG. 13), already discussed.

FIG. 15 shows an illustrative example of a computing apparatus 1500. In the illustrated example, the computing apparatus 1500 may include a processor 1502 and a memory 1504 communicatively coupled to the processor 1502. The memory 1504 may include computer readable instructions 1506, which may be implemented as software, for example. In an example, the computer readable instructions 1506, when executed by the processor 1502, implement one or more aspects of the method 1300 (FIG. 13), the quantum sensor system 200 (FIG. 2), already discussed.

In some implementations, the processor 1502 may include a general purpose controller, a special purpose controller, a storage controller, a storage manager, a memory controller, a micro-controller, a general purpose processor, a special purpose processor, a central processor unit (CPU), the like, and/or combinations thereof.

Further, implementations may include distributed processing, component/object distributed processing, parallel processing, the like, and/or combinations thereof. For example, virtual computer system processing may implement one or more of the methods or functionalities as described herein, and the processor 1502 described herein may be used to support such virtual processing.

In some examples, the memory 1504 is an example of a computer-readable storage medium. For example, memory 1504 may be any memory which is accessible to the processor 1502, including, but not limited to RAM memory, registers, and register files, the like, and/or combinations thereof. References to “computer memory” or “memory” should be interpreted as possibly being multiple memories. The memory may for instance be multiple memories within the same computer system. The memory may also be multiple memories distributed amongst multiple computer systems or computing devices.

FIG. 16 shows an illustrative semiconductor apparatus 1600 (e.g., chip and/or package). The illustrated apparatus 1600 includes one or more substrates 1602 and computer readable instructions 1604 (such as, configurable computer readable instructions (e.g., firmware) and/or fixed-functionality computer readable instructions (e.g., hardware)) coupled to the substrate(s) 1602. In an example, the computer readable instructions 1604 implement one or more aspects of the method 1300 (FIG. 13), the quantum sensor system 200 (FIG. 2), already discussed.

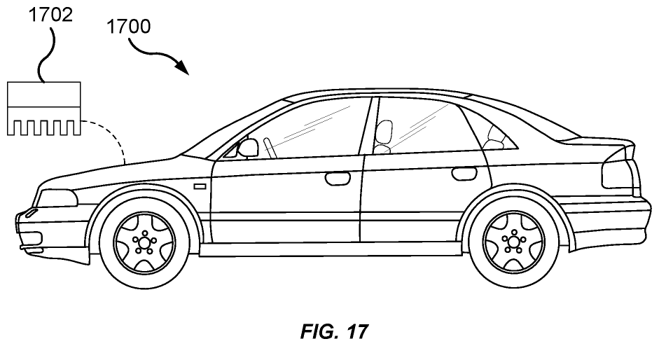

FIG. 17 is a diagram illustrating a vehicle 1700 according to an example. As illustrated, vehicle 1700 is an automobile. In other examples, vehicle 1700 may be a motorcycle, an electronic bicycle, an aircraft, the like, and/or combinations thereof.

In an example, the vehicle 1700 includes an electronics package 1702 coupled to vehicle. Such an electronics package 1702 incorporates one or more aspects the quantum sensor system 200 (FIG. 2), the quantum sensor system 300 (FIG. 3), the quantum sensor system 400 (FIG. 4), the quantum sensor system 500 (FIG. 5), the quantum sensor system 700 (FIG. 7), and/or the quantum sensor system 800 (FIG. 8), already discussed.

In some implementations, computer readable instructions 1604 may include transistor array and/or other integrated circuit/IC components. For example, configurable firmware logic and/or fixed-functionality hardware logic implementations of the computer readable instructions 1604 may include configurable computer readable instructions such as, for example, programmable logic arrays (PLAs), field programmable gate arrays (FPGAs), complex programmable logic devices (CPLDs), or fixed-functionality computer readable instructions (e.g., hardware) using circuit technology such as, for example, application specific integrated circuit (ASIC), complementary metal oxide semiconductor (CMOS) or transistor-transistor logic (TTL) technology, the like, and/or combinations thereof.

All definitions, as defined and used herein, should be understood to control over dictionary definitions, definitions in documents incorporated by reference, and/or ordinary meanings of the defined terms.

Furthermore, for ease of understanding, certain functional blocks may have been delineated as separate blocks; however, these separately delineated blocks should not necessarily be construed as being in the order in which they are discussed or otherwise presented herein. For example, some blocks may be able to be performed in an alternative ordering, simultaneously, etc.

The terms “coupled,” “attached,” or “connected” may be used herein to refer to any type of relationship, direct or indirect, between the components in question, and may apply to electrical, mechanical, fluid, optical, electromagnetic, electro-mechanical or other connections. Additionally, the terms “first,” “second,” etc. are used herein only to facilitate discussion, and carry no particular temporal or chronological significance unless otherwise indicated. The terms “cause” or “causing” means to make, force, compel, direct, command, instruct, and/or enable an event or action to occur or at least be in a state where such event or action may occur, either in a direct or indirect manner.

Although a number of illustrative examples are described herein, it should be understood that numerous other modifications and examples can be devised by those skilled in the art that will fall within the spirit and scope of the principles of the foregoing disclosure. More particularly, reasonable variations and modifications are possible in the component parts and/or arrangements of the subject combination arrangement within the scope of the foregoing disclosure, the drawings and the appended claims without departing from the spirit of the foregoing disclosure. In addition to variations and modifications in the component parts and/or arrangements, alternative uses will also be apparent to those skilled in the art. The examples may be combined to form additional examples.

We claim:

1. An apparatus comprising:
a substrate having a first side and a second side positioned opposite the first side;
a semiconductor device located on the second side of the substrate; and
a quantum sensor located on the second side of the substrate, wherein the quantum sensor comprises a layer of 2-D material, and wherein the quantum sensor further comprises a microwave field source, a light source, and a photodetector.

2. The apparatus of claim 1, wherein the quantum sensor is configured to measure one or more of a magnetic field, a temperature, or a strain field effect.

3. The apparatus of claim 1, wherein the quantum sensor further comprises a plurality of light pipes located between the light source and the layer of material and located between the photodetector and the layer of 2-D material.

4. The apparatus of claim 1, further comprising:
an electronics package, wherein the semiconductor device is contained within the electronics package, and
wherein the microwave field source, the light source, and the photodetector are incorporated into the electronics package.

5. The apparatus of claim 1, wherein the microwave field source, the light source, and the photodetector are incorporated into an electronics device positioned adjacent to the layer of 2-D material.

6. The apparatus of claim 1, wherein the semiconductor device comprises an active area and a non-active area,
wherein the quantum sensor comprises a plurality of quantum sensors, and
wherein the plurality of quantum sensors are located at one or more of one or more corner regions of the non-active area, one or more wire bond free regions of the non-active area, or one or more wire bond adjacent regions of the active area.

7. The apparatus of claim 1, wherein the layer of 2-D material has a design, wherein the design is one of a single unitary patch, an array of a plurality of patches, or a discontinuous patch having a geometric pattern.

8. The apparatus of claim 1, further comprising a temperature sensor located on the second side of the substrate, wherein the temperature sensor comprises a temperature sensing diode.

9. The apparatus of claim 1, wherein the substrate is a direct bond copper substrate, copper substrate, or composite substrate.

10. The apparatus of claim 1, wherein the semiconductor device is a power semiconductor device.

11. The apparatus of claim 1, wherein the layer of 2-D material comprises a hexagonal boron nitride 2-D material layer.

12. The apparatus of claim 11, wherein the hexagonal boron nitride 2-D material layer is formed via a tape transfer deposit or a chemical vapor deposition.

13. The apparatus of claim 1, further comprising a dielectric layer positioned between the quantum sensor and the semiconductor device.

14. A system comprising:
a vehicle; and
an electronics package coupled to the vehicle, the electronics package comprising:
a substrate having a first side and a second side positioned opposite the first side;
a semiconductor device located on the second side of the substrate;
a quantum sensor located on the second side of the substrate, wherein the quantum sensor comprises a layer of 2-D material, and wherein the quantum sensor further comprises a microwave field source, a light source, and a photodetector; and
a case containing the substrate, semiconductor device, and quantum sensor.

15. The system of claim 14, wherein the quantum sensor further comprises a plurality of light pipes located between the light source and the layer of 2-D material and located between the photodetector and the layer of 2-D material, and
wherein the microwave field source, the light source, and the photodetector are incorporated into the case the electronics package.

16. The system of claim 14, wherein the layer of 2-D material has a design, wherein the design is one of a single unitary patch, an array of a plurality of patches, or a discontinuous patch having a geometric pattern.

17. A method comprising:
exciting, via a microwave field source and a light source of a quantum sensor, a layer of 2-D material of the quantum sensor, wherein the quantum sensor is located adjacent a semiconductor device;
sensing, via a photodetector of the quantum sensor, the excitation of the layer of 2-D material;
measuring one or more of a magnetic field, a temperature, or a strain field effect of the semiconductor device based on the sensed excitation of the layer of 2-D material; and
predicting a remaining useful life of the semiconductor device based on one or more of the measured magnetic field, the measured temperature, or the measured strain field effect.

18. The method of claim 17, further comprising channeling light from the light source and light to the photodetector via a plurality of light pipes located between the light source and the layer of 2-D material and located between the photodetector and the layer of 2-D material.

19. The method of claim 17, wherein the measuring is conducted using one or more of an optically detected magnetic resonance measurement, a digital image correlation measurement, or a fluorescence magnitude measurement.

20. The method of claim 17, wherein the measuring is conducted using a baseline measurement and a plurality of subsequent measurements.
